(19) United States
(12) Patent Application Publication
(10) Pub. No.: US 2017/0226631 A1
(43) Pub. Date: Aug. 10, 2017

(54) MANUFACTURING OF SUBSTRATES COATED WITH A CONDUCTIVE LAYER

(71) Applicant: AGC GLASS EUROPE, Louvain-La-Neuve (BE)

(72) Inventors: Oliver KAPPERTZ, Goettingen (DE); Lars MICHEL, Lauenfoerde (DE); Marc DATZ, Lauenfoerde (DE)

(73) Assignee: AGC GLASS EUROPE, Louvain-La-Neuve (BE)

(21) Appl. No.: 15/518,968

(22) PCT Filed: Oct. 20, 2015
(86) PCT No.: PCT/EP2015/074217

§ 371 Date: Apr. 13, 2017

(30) Foreign Application Priority Data
Oct. 22, 2014 (EP) 14189921.1

(51) Int. Cl. C23C 14/58; C03C 17/36

(52) U.S. Cl. CPC C23C 14/5813; C03C 17/3644; C03C 17/3613; C03C 17/3626; C03C 17/3642; C03C 17/366; C03C 17/3681; C03C 2217/212; C03C 2217/216; C03C 2217/281; C03C 2217/213; C03C 2217/27; C03C 2217/256; C03C 2218/156

(57) ABSTRACT

The invention relates to a technique of manufacturing a coated substrate (102) such as glass (104) carrying a conductive layer (112) such as a metal layer to be tempered after deposition. A system (100) for manufacturing the coated substrate (102) may comprise a sputtering configuration (120) adapted for depositing the conductive layer (112) on the substrate (104). A pulse laser (132) is adapted for irradiating the conductive layer (112) with laser pulses (136). The pulse laser (132) is adapted for laser pulses (136) with a pulse duration below one microsecond.

The invention relates to a method of manufacturing a coated substrate including a conductive layer, a system for manufacturing a coated substrate, and a use of a pulsed laser for manufacturing a coated substrate.

Transparent substrates made of glass or of a synthetic material can be provided with one or more layers of coating for, e.g., adjusting optical properties such as transmissivity, for example in specific wavelength ranges, adjusting mechanical properties such as a breaking or fracturing behaviour, providing mechanical or chemical protection for other layers, etc.

Various products comprising a coated substrate may in particular comprise a layer of a conductive material, for example metallic material comprising one or more of copper, silver, aluminum, titanium nitride, transparent conducting oxides (TCO) including doped metal oxides, etc., the purpose thereof for example comprising a reflection of solar and/or infrared radiation, act as an ohmic contact for carrier transport out of a photovoltaic layer, etc.

The deposition of the conductive coating may at first instance lead to a layer comprising a fine-grained mixture of crystalline areas. A heat treatment such as a tempering process may be applied to stimulate a re-crystallization including healing of crystal defects, growth of monocrystalline structures, etc. and to thereby improve on optical property and/or other properties of the conductive layer and the final product. It is known that such heat treatment may include irradiating the conductive layer with laser radiation.

WO 2013/156721 A1 describes a method for producing a substrate provided with a coating. The method includes a step of depositing said coating onto said substrate, and a step of heat-treating said coating using continuous or pulsed laser radiation focused on said coating in the form of at least one laser line.

Heat treatment of a conductive layer, e.g., a silver layer, may however negatively affect properties of other layers of the coating system. Avoiding such effects may require coating other layers only after tempering of the conductive layer, which results in a complex and expensive manufacturing process. The necessity for a heat treatment may also rule out specific materials which would otherwise be suited for the coating system, which may tend to limit achievable properties of the manufacturing product and/or increases costs due to the necessity to use other materials. Still further, if a heat treatment cannot be performed as desirable for optimized properties of a conductive layer, for example because of limited energy input, the resulting properties of the conductive layer are also compromised.

The object of the invention is to provide a cost-efficient manufacturing method and system which enables an optimized heat treatment of a conductive layer such as a metal layer, for example a silver layer, of a coated substrate with a minimized deterioration of other coating layers.

The above object is solved by a method of manufacturing a coated substrate according to claim 1, a system for manufacturing a coated substrate according to claim 12, and a use of a pulsed laser for manufacturing a coated substrate according to claim 14.

According to one aspect of the invention, a method of manufacturing a coated substrate is proposed, which comprises depositing on the substrate a coating system comprising in order from the glass substrate outwardly at least a first dielectric layer, a conductive infrared radiation reflecting layer and a second dielectric layer, and irradiating the conductive layer with laser pulses. A pulse duration of the laser pulses is below one microsecond.

The substrate may comprise any kind of glass as it may be provided for float glass, sheet glass for windows, doors, balustrades, etc., architectural glass, safety glass, glass with low emissivity (‘low-E’) properties, but also solar panels or solar cells such as photovoltaic elements, solar heat elements or solar collector elements, light-emitting diodes (LEDs), etc. The substrate may additionally or alternatively comprise one or more synthetic materials and may comprise, for example, plastic glass or synthetic foils, for example foils to be fitted during manufacture of laminated glass between glass sheets.

The coated substrate comprises a coating system on at least one side of the substrate, wherein the coating system comprises more than one layer of coating. For providing the coating system on the substrate, a coating process may be performed which may comprise depositing more than one layer including the conductive layer, wherein one or more layers may be deposited prior to and/or subsequently to depositing the conductive layer on the substrate.

The infrared radiation reflecting conductive layer may comprise one or more metals, e.g. in the form of one or more metal layers, in the form of an alloy or a mixture of one or more metals, or in the form of a doping of one metal by another metal (for example silver doped with palladium). The metal may comprise one or more of copper (Cu), silver (Ag), aluminum (Al). The conductive layer is said to be homogeneous, meaning that mixing of the constituents is taking place at the atomic level and no clusters of one material inside a matrix of a second material can be discerned. As an example, when used herein, the term ‘silver-comprising layer’ may include silver layers which purely consist of silver disregarding unavoidable impurenesses, contaminations, etc., i.e. layers which include silver near to 100 at. % (atomic percent). The term ‘silver-comprising layer’ may however also include layers comprising silver to at least 90 at. %, at least 70 at. %, at least 50 at. %, at least 30 at. %, or at least 10 at. %. Preferably, the term ‘silver-comprising layer’, when used herein, is used for a layer whose major component is silver. This may hold similarly for any other metal or combination of metals in the conductive layer.

As used herein, the term ‘depositing a coating layer on a substrate’ may include that a layer is in fact deposited directly on the substrate, but may also include that a layer is in fact deposited on one or more previously deposited layers, i.e. even a layer said to be deposited ‘on the substrate’ may be spaced apart from the substrate by other layers.

Deposition of one or more coating layers on a substrate may be performed based on various deposition techniques known as such. For example, the conductive layer may be deposited via a sputtering process. The sputtering process may for example comprise one or more of the following techniques: DC (“direct current”)/AC (“alternating current”) sputtering, HF (“high frequency”)/RF (“radio frequency”) sputtering, reactive sputtering, gas flow sputtering, ion beam sputtering, magnetron sputtering including HiPIMS (“high power impulse magnetron sputtering”), etc. Other examples for deposition techniques may include wet coating techniques, evaporation techniques, etc.

According to various embodiments, the step of irradiating the conductive layer may be performed after the coating process is completed, i.e. the entire coating system is deposited first, which may include that the conductive layer is covered by one or more other layers, and the conductive layer is irradiated only subsequently to the finalized coating process. Additionally or alternatively, the irradiating step may be performed in parallel to the coating. For example, a pulse laser may be included into a coating line. Annealing may then be performed (at a position) immediately after conductive layer deposition (e.g., Ag deposition). Such approach may help to avoid a later cracking of the layer stack.

According to various embodiments, a pulse duration of at least some of the laser pulses may be less than 100 nanoseconds, preferably less than 50 nanoseconds. Depending on the details of any specific application, an optimum pulse duration may generally be expected to be between 1 nanosecond and 50 nanoseconds.

A pulse frequency of the laser pulses may be selected between 1 kilohertz and 100 kilohertz, preferably between 3 kilohertz and 30 kilohertz. According to specific embodiments, the pulse frequency may be selected around 10 kilohertz.

According to various embodiments, a wavelength of a radiation of the laser pulses is between 500 nanometers (nm) and 2500 nm, preferably between 1000 nm and 1100 nm.

According to various embodiments, a fluence of at least some of the laser pulses is between 0.2 millijoule per square millimeter and 100 millijoule per square millimeter, preferably between 1 millijoule per square millimeter and 20 millijoule per square millimeter. A required fluence depends on the desired annealing result. Based on the required fluence, an appropriate combination of pulse energy, pulse duration, power, spot size, etc. may be selected.

According to various embodiments, a pulse energy per pulse of at least some of the laser pulses may be selected between 1 millijoule and 1000 millijoule, preferably between 10 millijoule and 300 millijoule, more preferably between 30 millijoule and 150 millijoule, most preferably between 50 millijoule and 80 millijoule.

According to various embodiments, the laser pulses are applied as spots on the coated substrate, wherein the spots may have any shape, such as circular, oval, rectangular, quadratic, etc. on the coated substrate. According to some embodiments, shapes may be preferred which enable covering the coated substrate surface to be irradiated by repetitive patterning with minimized overlap which means that for any point of the coated substrate surface the desired energy input is achieved by one laser pulse only.

Pulse spot areas may be between about 0.5 square millimeters and about 50 square millimeters, preferably between 5 square millimeters and 20 square millimeters. According to specific embodiments, pulse spot areas may be around 10 square millimeters.

Referring arbitrarily to quadratic pulse spot sizes, according to some embodiments spot sizes may be between 1 millimeters (mm)×1 mm and 10 mm×10 mm. According to some currently preferred embodiments, pulse spot sizes may be around 3 mm×3 mm.

Irradiating the coated substrate including the conductive layer may comprise positioning multiple spots on the substrate surface, i.e. each pulse affects a different spot on the coated substrate. Sequences of spots may be positioned for example next to each other with or without overlap on the coated substrate.

According to various embodiments, during the irradiating step, a relative dislocation between a source of the laser pulses and the coated substrate may occur, for example due to an active transport of the coated substrate. The relative dislocation may be between 0.1 and 20 in units of square centimeters per second and watt.

According to various embodiments, the depositing step may comprise that at least a first dielectric layer, the conductive layer and a second dielectric layer are deposited on the substrate. The irradiating step may then comprise irradiating the conductive layer via at least one of the dielectric layers.

According to various embodiments, the depositing step may comprise that multiple conductive layers are deposited on top of each other on the substrate. For example, two metal layers such as, e.g., silver-comprising layers may be separated from each other by at least one or more dielectric layers, barrier layers, etc. Layer stacks with three, four, or more conductive layers may be laser treated. An energy input provided by the laser pulses during the irradiating step may be selected to simultaneously achieve a desired tempering of the multiple conductive layers.

According to various embodiments, the depositing step may comprise depositing on the substrate an absorption/reflection layer for absorbing/reflecting at least one of solar and/or infrared radiation. Depending on the wavelength of the laser radiation providing the laser pulses, such absorption/reflection layer may be positioned on a side of the conductive layer which is opposite to a side of the conductive layer onto which the laser pulses are irradiated.

According to one aspect of the invention, a system for manufacturing a coated substrate is proposed. The system comprises a component adapted for depositing a conductive layer on the substrate. The component may comprise, for example, a sputtering configuration. The system further comprises a pulse laser adapted for irradiating the conductive layer with laser pulses. The pulse laser is adapted for laser pulses with a pulse duration below one microsecond.

According to various embodiments, the pulse laser may comprise at least one of an Yb:YAG laser, Nd:YAG laser, and Nd:glass laser. Other laser equipment adapted or adaptable to provide short laser pulses in the range of nanoseconds or shorter can be contemplated.

According to some embodiments, the system comprises and/or is adapted for the following layer composition of a coated substrate:

According to some embodiments, the system comprises and/or is adapted for manufacturing the following layer composition of a coated substrate: Glass/dielectric layer/conductive layer/dielectric layer. Specific of these embodiments may implement a specific variant of a low-E-product: Glass/barrier layer/BiOₓ (bismuth oxide) and/or Si₃N₄ (silicon nitride)/Ag (silver) and/or other conductive material/NiCr (nickel chromium)/BiOₓ. The or any barrier layer may function as a diffusion barrier.

As used herein, the term ‘oxide’ and corresponding abbreviation ‘Oₓ’ may generally refer to an unspecified degree of oxidation, for example because the corresponding layer is not fully oxidized, which implies the parallel presence of a variety of oxides such as monoxides, dioxides, etc. in arbitrary shares.

According to some embodiments, the system comprises and/or is adapted for manufacturing the following layer composition of a coated substrate, which may implement another specific variant of a low-E-product: Glass/optionally SiOₓ (silicium oxide) and/or Si₃N₄ (silicon nitride)/TiOₓ (titanium oxide)/ZnO (zinc oxide) or ZnO:Al/Ag and/or other conductive material/ZnO or ZnO:Al/TiOₓ/ZnSnOₓ (zinc stannate)/optionally Si₃N₄ and/or SiOₓ. Optionally, the stack can comprise an additional top coating layer (i.e., a layer on top of the stack), which may contain TiOₓ with or without doped alloys.

According to some embodiments, the system comprises and/or is adapted for manufacturing the following layer composition of a coated substrate, which may implement a specific variant of a double low-E-product (dual silver)/solar protection product: Glass/DE1/Ag (and/or other conductive layer)/DE2/Ag (and/or other conductive layer)/DE3, wherein DE1, DE2, DE3 denote each a dielectric layer. Such layer may contain TiOₓ, SnZnOₓ, SiₓN_{y}, SiOₓN_{y}, SiOₓC_{y}, SiOₓN_{y}C_{z}, ZnO (optionally doped with, e.g., Al or Sb), SnOₓ, NbOₓ, HfOₓ, or mixtures or alloys thereof. A dielectric layer may contain one or more sublayers. Between glass and DE1, one or more additional layers may be added. Between a dielectric layer below an Ag layer and the Ag layer, there may be a seed layer. Between a dielectric layer on top of an Ag layer and the Ag layer, there may be a blocker layer. As a specific example, the following coating system may be provided: Glass/TiOₓ/ZnOₓ/Ag and/or other conductive material/ZnOₓ/ZnSnOₓ/ZnOₓ/Ag and/or other conductive material/ZnOₓ/TiOₓ/ZnSnOₓ.

According to some embodiments, the system comprises and/or is adapted for manufacturing the following layer composition of a coated substrate, which may implement a specific variant of a solar protection product: Glass/optionally SiOₓ and/or Si₃N₄ (or other dielectric)/NiCr/optionally SiOₓ and/or Si₃N₄ (or other dielectric)/TiOₓ/ZnOₓ/Ag and/or other conductive material/ZnOₓ/TiOₓ/ZnSnOₓ/optionally Si₃N₄ and/or SiOₓ. Instead of NiCr, another absorber could be employed, e.g., nitrides or carbides or mixtures or alloys of Cr, Ni, Ti, V, W.

According to one aspect of the invention, use of a pulse or pulsed laser for manufacturing a coated substrate is proposed. When a silver-comprising layer has been deposited on the substrate, the pulse laser may be employed for irradiating the silver-comprising layer with laser pulses. Specifically, the pulse laser is adapted for laser pulses with a pulse duration below one microsecond.

According to various embodiments, at least one of the following laser types can be used: regarding a laser medium, solid-state laser or gas laser (e.g., CO₂-laser) could be used, regarding an excitation or operation mode, Q-switched laser, mode lock laser, pulsed excitation laser, continuous wave (CW) laser could be used, with corresponding pulse lengths. For example, short pulse or pulsed laser could be employed, or a required pulse length could be generated based on, e.g., a CW laser by additional means, such as an optical modulator.

According to various embodiments of the invention, an amount of energy as required for a desired heat treatment of a conductive layer, e.g. a metal-comprising layer such as a silver-comprising layer of a coated substrate is deposited as short laser pulses instead of a more continuous irradiation. The short laser pulses have a duration below 1 microsecond, and according to various exemplary embodiments may have a duration of about 100 nanoseconds, 10 nanoseconds or 1 nanosecond, for example.

Surprisingly it turns out that such type of heat treatment enables an optimized tempering of the conductive, e.g., silver-comprising layer while on the other hand negative effects on said layer and/or other coating layers can be minimized. For example, crack formation can at least be limited such that deterioration of one or more of optical properties, conductive properties, chemical and/or mechanical stability is minimized.

It is assumed that depositing a desired energy in form of short laser pulses as defined herein results in an adiabatic or near-adiabatic heating of the conductive layer. In other words (assuming that the irradiated energy is absorbed predominantly by the conductive layer), as the total energy is deposited in pulses with a duration which may be shorter than timescales of energy dispersion, e.g. thermal dispersion, heat conduction, etc., a loss of energy by flow to other coating layers and/or the substrate is minimized in such a way that a deterioration of properties of the conductive layer and/or other coating layers can be minimized or avoided.

The details of how to achieve the supposed near-adiabatic effect may depend on the specifics of a desired product, i.e. desired configuration of substrate and coating system, including coating materials and desired tempering effects on the conductive layer, etc. Accordingly, specific values for energy input per unit or spot area, total pulse energy, pulse duration, duty cycle, wavelength, spot size, processing velocity, etc. may be applied. For example, it may depend on the specific circumstances of any particular application whether a pulse duration of 100 ns, 10 ns, or 1 ns is sufficient to achieve one or more desired effects, wherein it is presently contemplated that optimum values for most applications may be found in a range of values between 50 nanoseconds and 1 nanosecond.

Various embodiments of the invention allow depositing some or all layers of a coating system prior to annealing one or more conductive layers embedded in the coating system, as detrimental effects of the annealing on the conductive layer and/or the other layers can be minimized. This enables to simplify the manufacturing process with corresponding cost-reductions.

Based on various embodiments of the invention, for specific applications coating materials and/or layer compositions can be considered which would otherwise be ruled out due to their properties being negatively affected by conventional tempering processes of a conductive, e.g. a silver-comprising layer.

As various embodiments of the invention allow minimizing negative effects of tempering a conductive layer, inevitable tolerances for optical and/or other properties of the coated substrate can be reduced as compared to conventionally manufactured products.

Various embodiments of the invention allow manufacturing processes with increased energy efficiency. Compared to conventional processes, energy can be saved if energy dispersion is minimized by sufficiently short energy deposition times, i.e. laser pulse durations. Therefore less energy per unit area of coated substrate need to be irradiated, or vice versa for a given laser configuration a larger area can be irradiated.

In the following, the invention will further be described with reference to exemplary embodiments illustrated in the drawing by way of example only. In the drawing

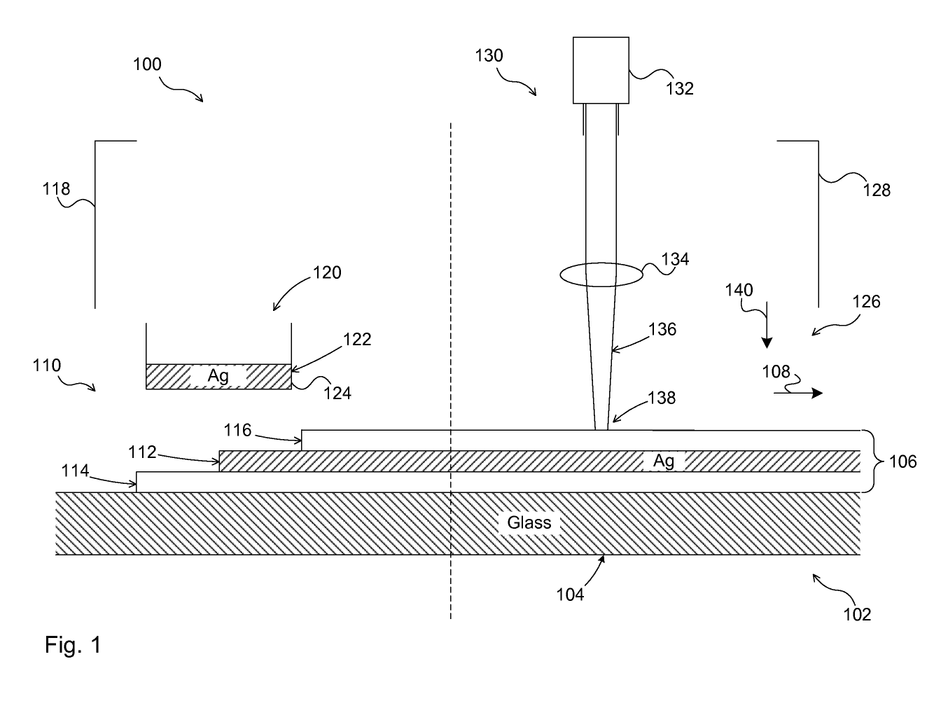

FIG. 1 schematically illustrates an embodiment of a system for manufacturing a coated substrate according to the invention;

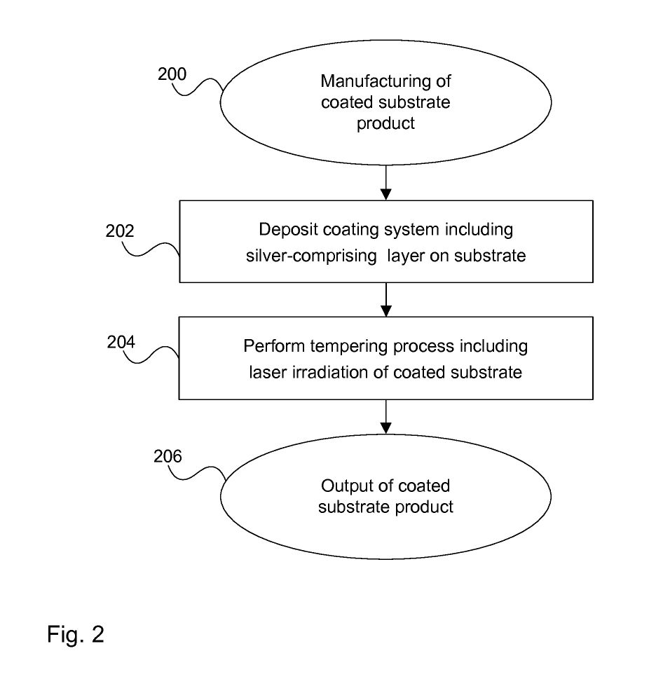

FIG. 2 is a flow diagram illustrating an operation of the system of FIG. 1;

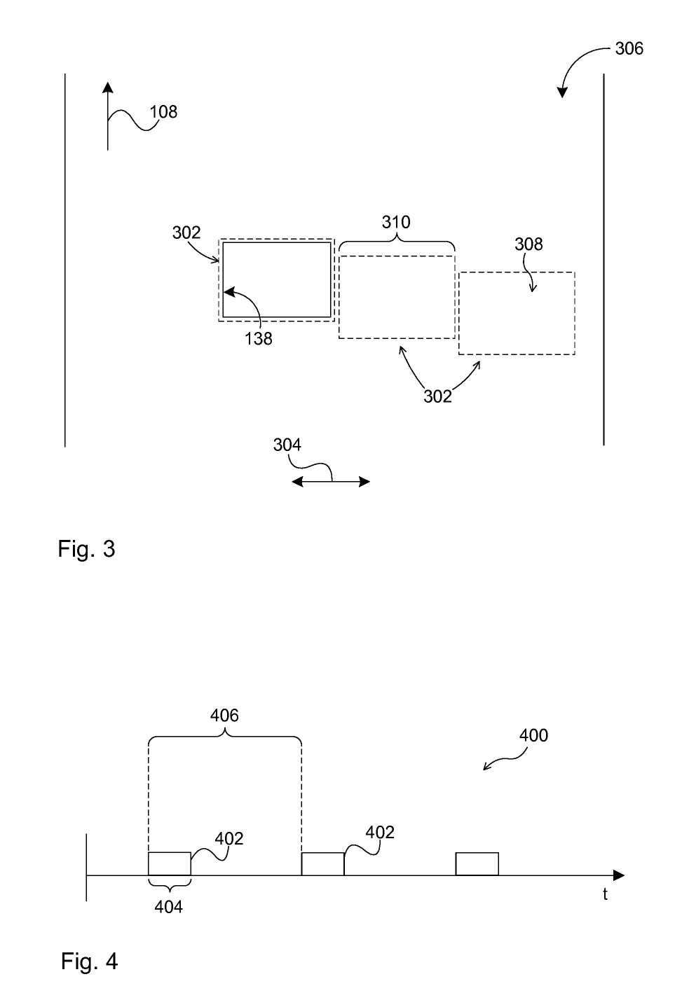

FIG. 3 schematically illustrates spots of laser pulses on a coated substrate according to an embodiment of the invention;

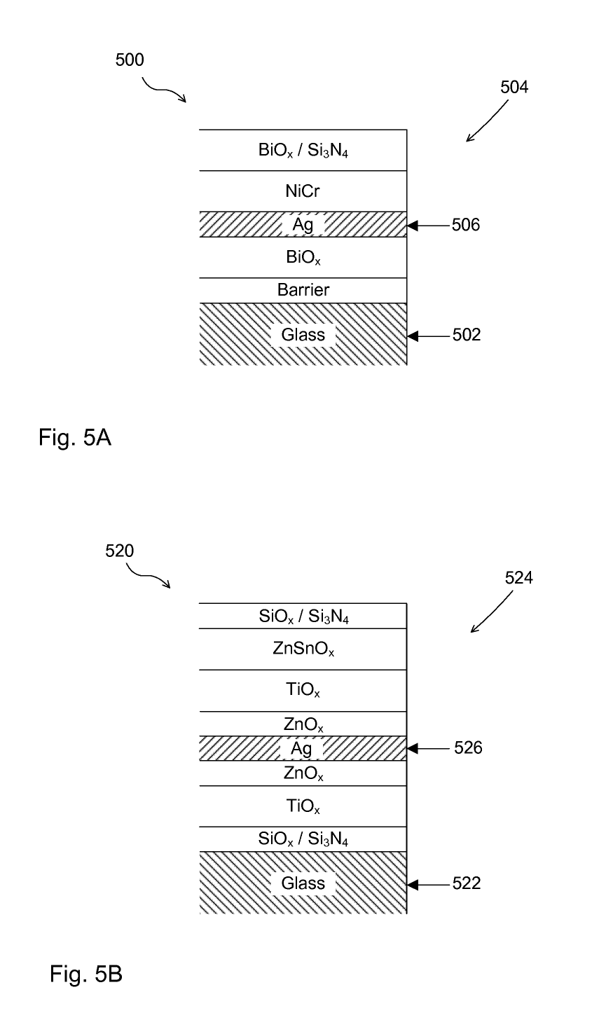

FIG. 4 illustrates a time sequence of laser pulses irradiated onto a coated substrate according to an embodiment of the invention;

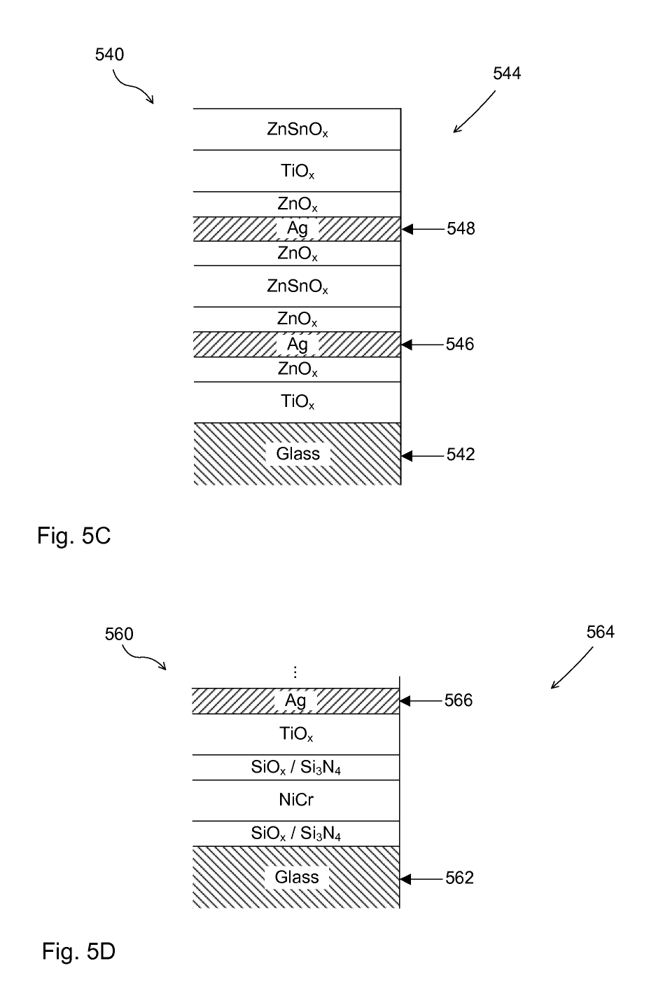

FIG. 5A schematically illustrates a first specific embodiment of a coating system manufactured according to the invention;

FIG. 5B schematically illustrates a second specific embodiment of a coating system manufactured according to the invention;

FIG. 5C schematically illustrates a third specific embodiment of a coating system manufactured according to the invention; and

FIG. 5D schematically illustrates a fourth specific embodiment of a coating system manufactured according to the invention.

FIG. 1 schematically illustrates a system or plant 100 for manufacturing a product 102 comprising a substrate 104 with a coating system 106 being deposited during a manufacturing process. The product 102 may be a pre-product intended for further manufacturing after output from system 100, however is referenced only as a ‘product’ herein for short. System 100 may comprise more than the sections and functions illustrated in FIG. 1 and discussed hereinbelow, however such other sections and functions are currently considered not indispensable for implementing the invention and are therefore omitted.

It is assumed that substrate 104 is transported from left to right as indicated by arrow 108 such that FIG. 1 may also be interpreted as illustrating a sequence in time of manufacturing product 102. An operation 200 of system 100 for manufacturing the product 102 will be described with additional reference to the flow diagram of FIG. 2.

The manufacturing process 200 comprises a step 202 of performing a coating process for depositing the coating system 106 on the substrate 102. The coating process 202 is illustrated schematically by section 110 of system 100 in FIG. 1.

Specifically, substrate 104 may comprise a glass substrate. The coating process 202 may comprise depositing a conductive layer, specifically a silver-comprising layer 112 on the glass substrate 104. The coating process 202 may further comprise depositing other layers below 114 and above 116 silver layer 112 on the substrate 104. Layers 114, 116 may comprise multiple sublayers and may comprise one or more of a dielectric layer, barrier layer, another silver layer, etc.

Section 110 of system 100 may comprise a process chamber 118 for example for providing vacuum (evacuated, low pressure) conditions for depositing one or more of the layers 112, 114, 116. Specifically, as indicated in FIG. 1, a sputtering configuration 120 may be provided which includes a sputtering target 122 for providing a target material 124. For a sputtering process for depositing the silver-comprising layer 112, the target material 124 may comprise silver and optionally other materials such as one or more dopants for optimizing the sputtering process, optical or other properties of the product 102, etc.

In step 204, the substrate 104 coated with the coating system 106 is subjected to a tempering process for optimizing properties of the sputtered silver-comprising layer 112. The tempering process 202 is illustrated schematically by section 126 of system 100 in FIG. 1.

According to the specific example illustrated in FIG. 1, the coated substrate 104/106 is transported along the direction indicated by arrow 108 from section 110 to section 126. Section 126 may comprise a process chamber 128 which may not necessarily provide vacuum conditions, but which conforms to safety prescriptions for laser systems.

Substrate 104 and coating system 106 are illustrated as continuously transported along sections 110 and 126, however in practical implementations the chambers 118 and 128 may each be configured for processing product 102 as a piece of coated substrate of predefined dimensions; for example, the pieces may be rectangular with side lengths of several meters. Therefore, chambers 118 and 128 may in general be implemented as separate chambers which may be spaced apart from each other, optionally with other compartments or chambers between. According to some embodiments, chamber 128 may be located near the end of a manufacturing line implementing the system 100 and may for example comprise the last compartment prior to a gate for outputting the coated substrate 104/106, i.e. product 102.

The tempering process of step 204 in section 126 may comprise irradiating the coated substrate 104/106 with laser radiation. In this respect, laser configuration 130 is provided which may comprise, amongst others, a laser 132 and irradiation arrangement 134. Specifically, laser 132 may comprises one or more pulse lasers (also termed ‘pulsed lasers’ in the field) specifically adapted for providing short pulses of pulse duration below 1 microsecond, i.e. in the range of nanoseconds. A presently preferred range is between 1 nanosecond and 50 nanoseconds, which does not exclude applications with pulses even in the range of picoseconds. Additionally or alternatively to truly pulsed lasers, short pulses may be generated from longer pulses or continuous laser radiation by the irradiation arrangement, e.g. by appropriately opening and closing an aperture.

Laser radiation 136 comprising short laser pulses is provided via irradiation arrangement 134 to coated substrate 104/106 in an incidence area 138. Irradiation arrangement 134 may comprise focusing, beam-forming and/or positioning arrangements for correspondingly modifying laser radiation 136.

The laser 132 may comprise a solid-state laser and/or a Q-switched laser. It may take the form, for example, of a disk laser or a fiber laser. As specific examples, the pulse laser 132 may comprise an neodymium-doped glass or ceramics laser (e.g., Nd:YAG), a neodymium-doped glass laser (Nd:glass) and/or an ytterbium-doped glass or ceramics laser (e.g., Yb:YAG), wherein choice of laser type may depend on the available pulse energies. Wavelengths of emitted laser radiation 136 of 1030 nanometers (nm) (Yb:YAG), 1064 nm (Nd:YAG) and/or 1070 nm (Nd:glass) have been found appropriate. Other types of laser could be used, for example, Er:YAG or Ho:YAG laser, optionally with second, third or higher order harmonic generation. Other wavelengths may be preferred depending on absorption properties in the conductive layer 112 and/or transparency properties of the other layers 114, 116. For other embodiments, optionally also a transparency of the substrate for laser radiation has to be considered if an irradiation of the conductive layer is performed via the substrate.

In step 206, the manufacturing process 200 ends, for example by providing the coated and tempered product 102 to further or other manufacturing equipment, e.g. for portioning, etc.

FIG. 3 schematically illustrates a view from above as indicated by arrow 140 in FIG. 1 onto the coated substrate 104/106. Shown by dashed lines are spots 302 wherein each spot 302 marks the impact of a pulse of laser radiation 136 onto the coated substrate 104/106 in incidence area 138. Spot 302 size may be formed by irradiation arrangement 134 on the coated substrate 104/106. It is noted that dimensions of the coated substrate 104/106 and of the spots 302/incidence area 138 may not be drawn to scale. Various non-overlapping or contacting spots 302 are shown in FIG. 3 for clarity. However, in a practical implementation various spots may contact or overlap each other to form an overall irradiated surface.

If a single laser 132 is employed, irradiation arrangement 134 may arrange for a lateral displacement of incidence area 138 along directions indicated by double arrow 304 to form a sequence of spots 302 side-by-side. Due to a relative dislocation between laser source 130 and coated substrate 104/106, e.g. due to a transport of the coated substrate 104/106 into the direction indicated by arrow 108 and/or a movement of a focusing section of irradiation arrangement 134, subsequent spots may be shifted along the transversal direction 108 as indicated in FIG. 3. According to other embodiments, a laser device may not only be arranged for lateral displacement as indicated with arrow 304 in FIG. 3, but may alternatively additionally be arranged for transversal displacement.

Details of how to achieve complete coverage of the surface 306 of coated substrate 104/106 to be irradiated for tempering the silver-comprising layer 112 are known to the skilled person. For example, the pulse impact areas or spots 302 are exemplarily shown as being of rectangular or nearly quadratic shape. While various shapes can be contemplated, a rectangular or quadratic spot shape can exemplarily be employed to achieve an efficient coverage of the area 306. As specific examples, the pulse spots 302 may cover an area 308 of about 10 square millimeters, wherein sides 310 of spots 302 may have lengths of about 3 millimeters. Sizes may vary during manufacturing for example according to varying incidence angles of the radiation 136.

Each spot 302 may preferably result from one and exactly one laser pulse to ensure desired energy input on adiabatic or near-adiabatic short timescale. Per spot 302, an energy, i.e. a pulse energy per laser pulse, between 10 millijoule and 300 millijoule may be deposited. As a specific example, the pulsed radiation 136 may have a fluence of between about 5 millijoule per square millimeter and 8 millijoule per square millimeter for each of the spots 302.

FIG. 4 illustrates a time sequence 400 of laser pulses 402 of radiation 136 irradiated onto the coated substrate 104/106. A pulse duration 404 and time span 406 may not be drawn to scale.

Specifically, the sequence 400 of pulses 402 may result in the sequence of spots 302 illustrated in FIG. 3. A pulse duration 404 of the pulses may exemplarily be assumed to be 30 nanoseconds. The time 406 between successive pulses may exemplarily be assumed to be around 100 microseconds. As a result, a pulse frequency is about 10 kilohertz and a duty cycle of laser configuration 130 is about 0.0003. The duty cycle is understood herein as the ratio of a pulse duration to a time between two successive pulses. Generally, a duty cycle may be below 10%, preferably below 1%.

Pulses 402 are illustrated in FIG. 4 as having a common pulse duration 404, which may not generally or necessarily be the case. For example, pulse durations and/or spot sizes may vary according to an incidence angle of the irradiation 136. Generally, for a given type of laser a pulse duration is mostly fixed, i.e. can be varied only slightly around a fixed value, while pulse energy and/or intensity can be varied, in principle even from pulse to pulse. In practice, therefore, a desired specific energy input (i.e., per unit area) may be achieved for a given type of laser by varying a pulse energy, or may be achieved by considering a desired pulse duration (and energy) and selecting an appropriate type of laser.

The embodiments illustrated in FIGS. 1-4 may demonstrate the surprising insight that when a particularly short pulsed laser is used for depositing an energy required for tempering a silver-comprising layer (more generally, metal-comprising layer or conductive layer) of a coated substrate, it is possible to minimize negative effects of the tempering on the other coating layers. However, such insight is not dependent on the purely exemplary numerical values given above to further illustrate the invention. In fact, when representing technical configurations by sets of numerical values indicating, for example, pulse energy, pulse duration, spot size, etc., a plurality of different number sets can be contemplated, calculated and/or determined by experiments which can achieve one or more of the advantages of the invention. The choices of process parameter values depend on the specifics of the coating system including the conductive layer, the substrate and the desired tempering effect, the available laser system, etc.

As only one example, the energy to be absorbed by the conductive layer is determined by the desired tempering effects. Based on an amount of energy available per laser pulse, a spot size may then be calculated. As a further example, the pulse frequency of the laser pulses may be selected according to the properties of the employed laser, the employed irradiation arrangement, a desired relative transport velocity of laser configuration 130 vs. substrate 104, etc. Spot sizes and/or fluence may be set according to available energy per pulse and desired energy input per area of the coated substrate/conductive layer.

It is noted that according to preferred embodiments it is intended that any point of the coated substrate surface to be irradiated should be covered by one laser pulse spot only, which presumably is advantageous to achieve the adiabatic or near-adiabatic effects discussed further above. The energy to be irradiated and absorbed by the silver-comprising layer should preferably be irradiated to the incidence area/spot in a time short enough to achieve the adiabatic effect, i.e. the desired energy input should be irradiated in a short pulse in contrast to a conventional continuous emission or longer pulse of presumably lower irradiation intensity. On the other hand, the pulses do not need to be shorter as required for avoiding undesirable deteriorations of other coating layers.

FIGS. 5A to 5D illustrate examples of coated substrates including coating systems which can be manufactured by a system such as, for example, system 100 of FIG. 1 and according to a process such as, for example, process 200 of FIG. 2. A silver-comprising layer is again considered as example for a conductive layer in a coated (glass) substrate. For each of the exemplary embodiments the tempering of the one or more silver-comprising layers may be performed after the respective coating system has been deposited on the substrate. It is to be noted that relative layer thicknesses as illustrated in FIGS. 5A-5D are not drawn to scale.

FIG. 5A illustrates a coated substrate 500 comprising a substrate 502 and coating system, stack, or layer composition 504. As illustrated, substrate 502 may comprise glass. The layer composition 504 includes multiple coating layers comprising a single silver layer 506 embedded within various other layers including dielectric layers. Substrate 502 and coating system 504 may be intended for a low-E product.

As illustrated in FIG. 5A, the coated substrate 500 comprises the following layers: Glass/barrier layer/BiOₓ and/or Si₃N₄/Ag/NiCr/BiOₓ. The barrier layer may, for example, comprise SiOₓ. Instead of NiCr, other absorber materials such as Ni alloys may be employed.

Surprisingly it has been found that when employing a short pulsed laser with pulses shorter than 1 microsecond for tempering the silver layer 506, one or more of the effects of the invention as discussed above can be achieved. In particular, a desired annealing of the silver layer 506 can be performed while minimizing negative effects on the other layers of coating system 504.

FIG. 5B illustrates a coated substrate 520 comprising a glass substrate 522 and coating system 524. The coating system 524 comprises multiple coating layers comprising a single silver layer 526 embedded within various other layers. The coated substrate 520 represents another example of a low-E product.

As illustrated in FIG. 5B, the coated substrate 520 comprises the following layers: Glass/optionally SiOₓ and/or Si₃N₄/TiOₓ/ZnOₓ/Ag/ZnOₓ/TiOₓ/ZnSnOₓ/optionally Si₃N₄ and/or SiOₓ. Instead of ZnSnOₓ, TiN could be used. The TiOₓ layers can have, for example, a thickness of about 20 nm-50 nm. The silver layer 526 may have a thickness of 1 nm-20 nm, preferred 4 nm-18 nm, more preferred 6 nm-17 nm. The precise value may be dependent on the intended ‘low-E’ emissivity properties, for a value of ∈=1.1 a preferred silver layer thickness may be between 10 nm-13 nm. A thickness of the optional barrier layers comprising SiOₓ and/or Si₃N₄ can be selected below 10 nm.

Surprisingly it has been found that when employing a short pulsed laser with pulses shorter than 1 microsecond for tempering the silver layer 526, one or more of the effects of the invention as discussed above can be achieved. In particular, a desired annealing of the silver layer 526 can be performed while minimizing negative effects on the other layers of coating system 524.

FIG. 5C illustrates a coated substrate 540 comprising a glass substrate 542 and coating system 544. The coating system 544 comprises multiple coating layers comprising two silver layers 546, 548 embedded within various other layers. The coated substrate 540 is an example of a double-low-E or low-E² product which can also be seen as having solar absorbing properties.

As illustrated in FIG. 5C, the coated substrate 540 comprises the following layers: Glass/TiOₓ/ZnOₓ/Ag/ZnOₓ/ZnSnOₓ/ZnOₓ/Ag/ZnOₓ/TiOₓ/ZnSnOₓ. Instead of ZnSnOₓ, TiN could be used. The upper ZnSnOₓ layer could be covered or replaced by SiOₓ or Si₃N₄ or TZO (tin-doped zinc oxide) as illustrated with the configuration of FIG. 5B. The ZnOₓ layers can for example have a thickness between 1 nm and 10 nm. The silver layers 546, 548 can each have a thickness between 1 nm and 20 nm, preferred between 5 nm and 16 nm. According to a specific configuration, the thickness of silver layer 546 may be around 8 nm, while the thickness of silver layer 548 may be less, and may be around 1 nm to below 8 nm.

Surprisingly it has been found that when employing a short pulsed laser with pulses shorter than 1 microsecond for simultaneously tempering the silver layers 546 and 548, one or more of the effects of the invention as discussed above can be achieved. In particular, a desired annealing of the silver layers 546 and 548 can be performed while minimizing negative effects on the other layers of coating system 544.

FIG. 5D illustrates in part a coated substrate 560 comprising a glass substrate 562 and coating system 564. The coating system 564 comprises multiple coating layers comprising a silver layer 566 embedded within various other layers. The coated substrate 560 is an example of a low-E product provided with an additional absorber layer 568.

As illustrated in FIG. 5D, the coated substrate 560 comprises the following layers: Glass/SiOₓ (and/or Si₃N₄)/NiCr/SiOₓ/TiOₓ/Ag/ . . . , wherein the layers above the silver layer 566 can be selected, for example, similar to the layers covering silver layer 526 in FIG. 5B. Ignoring the barrier layers SiOₓ, the absorber layer 568 can be positioned near to the glass substrate 562, as illustrated in FIG. 5D, and/or an absorber layer can be located at another position in a coating system. Instead of NiCr, other absorber materials may be used for the absorber layer 568, e.g. Cr, CrN, TiN, TiC (or absorbing oxides or suboxides of any one or more of these metals), and/or another Ni alloy may be employed.

Surprisingly it has been found that when employing a short pulsed laser with pulses shorter than 1 microsecond for tempering the silver layer 566, one or more of the effects of the invention as discussed above can be achieved.

According to one embodiment, the coating system 544 of FIG. 5C may be added with an absorber layer such as absorber layer 568 shown in FIG. 5D to arrive at a low-E² product with distinct solar absorbing properties.

A coating system such as system 524 of FIG. 5B may be deposited two times on a substrate to arrive at a double silver, low-E² product similar to system 544 of FIG. 5C. According to other embodiments, a coating system such as system 524 of FIG. 5B may be deposited three times to arrive at a triple silver product. Some of these embodiments may comprise additionally an absorber layer such as absorber layer 568 shown in FIG. 5D to arrive at a combined triple silver and absorber product.

According to modifications of the various above embodiments, there may be a seed layer positioned below each of one or more of the silver-comprising layers for facilitating growth of the corresponding silver-comprising layer. Additional layers may be provided, for example one or more top layers, and/or titanium-containing layers.

Any of the layers described herein may comprise multiple sublayers. For example, one dielectric layer may comprise several sublayers, e.g. a combination of two sublayers TiO₂/SiO₂.

According to various embodiments, a coating layer may implement more than one function. For example, a layer comprising Si₃N₄ can function as a barrier layer and at the same time as a dielectric layer with medium refractive properties.

While many of the embodiments described herein relate to products intended for some degree of transparency, the invention is equally applicable to the manufacture of mirrors and other kind of reflecting structures which may include one or more silver-comprising layers.

While the invention has been described in relation to its preferred embodiments, it is to be understood that this description is intended non-limiting and for illustrative purposes only. In particular, various combinations of features wherein the features have been described separately hereinbefore are apparent as advantageous or appropriate to the skilled artisan.

1: A method of manufacturing a coated substrate, the method comprising:
depositing on the substrate a coating system comprising in order from the glass substrate outwardly at least a first dielectric layer, a conductive infrared radiation reflecting layer and a second dielectric layer, and
irradiating the conductive layer with laser pulses, wherein
a pulse duration of the laser pulses is below one microsecond.

2: The method according to claim 1, wherein
the pulse duration is less than 100 nanoseconds.

3: The method according to claim 1, wherein
a wavelength of a radiation of the laser pulses is between 500 nanometers and 2500 nanometers.

4: The method according to claim 1, wherein
a fluence of the laser pulses is between 0.2 millijoule per square millimeter and 100 millijoule per square millimeter.

5: The method according to claim 1, wherein
a pulse energy per pulse of the laser pulses is between 1 millijoule and 1000 millijoule.

6: The method according to claim 1, wherein
a pulse frequency of the laser pulses is between 1 kilohertz and 100 kilohertz.

7: The method according to claim 1, wherein
the conductive layer comprises a metal.

8: The method according to claim 1, wherein
the conductive layer is a silver-comprising layer.

9: The method according to claim 1, wherein
the coating system deposited on the substrate comprises in order from the glass substrate outwardly at least a first dielectric layer, a first conductive layer, a second dielectric layer, a second conductive layer and a third dielectric layer.

10: The method according to claim 1, wherein
the coating system deposited on the substrate comprises at least one of the following: a barrier layer, a blocker layer, an absorber layer, a seed layer.

11: The method according to claim 1, wherein
said irradiating the conductive layer is performed after said depositing completion of the coating system deposition step.

12: A system for manufacturing a coated substrate, comprising:
a component adapted for depositing on the substrate a coating system comprising in order from the glass substrate outwardly at least a first dielectric layer, a conductive infrared radiation reflecting layer and a second dielectric layer, and
a pulse laser adapted for irradiating the conductive layer with laser pulses, wherein
the pulse laser is adapted for laser pulses with a pulse duration below one microsecond.

13: The system according to claim 12, wherein
the pulse laser comprises at least one of an Yb:YAG laser, Nd:YAG laser or Nd:glass laser.

14. (canceled)

15: The method according to claim 1, wherein
the pulse duration is less than 50 nanoseconds.

16: The method according to claim 1, wherein
a wavelength of a radiation of the laser pulses is between 1000 nanometers and 1100 nanometers.

17: The method according to claim 1, wherein
a fluence of the laser pulses is between 1 millijoule per square millimeter and 20 millijoule per square millimeter.

18: The method according to claim 1, wherein
a pulse energy per pulse of the laser pulses is between 10 millijoule and 300 millijoule.

19: The method according to claim 1, wherein
a pulse energy per pulse of the laser pulses is between 30 millijoule and 150 millijoule.

20: The method according to claim 1, wherein
a pulse energy per pulse of the laser pulses is between 50 millijoule and 80 millijoule.

21: The method according to claim 1, wherein
a pulse frequency of the laser pulses is between 3 kilohertz and 30 kilohertz.
